(19) United States
(12) Patent Application Publication
(10) Pub. No.: US 2007/0145576 A1
(43) Pub. Date: Jun. 28, 2007

(54) Power Semiconductor Circuit And Method Of Manufacturing A Power Semiconductor Circuit

(76) Inventor: Reinhold Bayerer, Warstein (DE)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/549,809

(22) Filed: Oct. 16, 2006

Related U.S. Application Data
(63) Continuation of application No. PCT/EP05/02708, filed on Mar. 14, 2005.

(30) Foreign Application Priority Data
Apr. 16, 2004 (DE) 10 2004 018 471.2

(51) Int. Cl. H01L 23/34

(52) U.S. Cl. 257/723

(57) ABSTRACT

The power semiconductor circuit has a power semiconductor module (2) provided in the form of a flat module. In order to utilize the design possibilities resulting therefrom and to provide a power semiconductor circuit that has an automatable production and a particularly space-saving design, the flat module, with its substrate (11), is glued by a heat conducting adhesive (20) directly onto a heat conducting base plate (1) that acts as a cooling element (5).

### CROSS-REFERENCE TO RELATED APPLICATION

This application is a continuation of co-pending International Application No. PCT/EP2005/002708 filed Mar. 14, 2005 which designates the United States, and claims priority to German application number DE 10 2004 018 471.2 filed Apr. 16, 2004.

### TECHNICAL FIELD

The invention relates to power semiconductor technology. The invention relates to a power semiconductor circuit for a converter circuit, and to a method for manufacturing said circuit.

### BACKGROUND

In a power semiconductor circuit as disclosed in EP 0 901 166 A1 a power semiconductor module is designed using conventional technology: One or more individual power semiconductor elements, for example IGBTs (subsequently also referred to as power semiconductors), are connected to the top side of an aluminum nitride substrate via a solder layer and a metallization. The bottom side of the substrate is encapsulated with a cooling device in form of a ribbed heat sink.

A new trend in module configuration heading towards flat module geometries by using lamination methods is described, for example, in the article “A High Performance Polymer Thin Film Power Electronics Packaging Technology” by Ray Fillion et al. in Advancing Microelectronics, September/October 2003.

For producing such a module, for instance a substrate with a device having a contact area can be provided. In this case, a contact of low inductance is realized by bringing the contact area together with a pad which is formed on a relatively thin film. The contact area and the pad are brought together by laminating the film in a vacuum press under isostatic pressure.

### SUMMARY

A power semiconductor circuit may comprise a power semiconductor module in the form of a flat assembly in which at least one electronic power device is arranged on a substrate. The at least one device can be contacted to a pad of a laminated film with a contact area located on the top side. The substrate can be directly fastened to a thermally conductive base plate which acts as a cooling element. Suitable fastening methods and means such as adhesive bonding, crimping, latching using latching hooks, screwing using threaded elements etc. may be considered.

### BRIEF DESCRIPTION OF THE DRAWINGS

Subsequently, the invention is explained in more detail with reference to exemplary embodiments which are illustrated in the figures, in which:

FIG. 1 shows a perspective view of a power semiconductor circuit, and

FIG. 2 shows a side view of the power semiconductor circuit of FIG. 1.

### DETAILED DESCRIPTION

Thus, according to an embodiment a particularly flat power semiconductor circuit can be realized by using the flat design of the novel power semiconductor module described above. A technique is provided this way which, departing from the conventional design and the conventional housing of power semiconductor modules, enables a particularly flat and compact arrangement. The power semiconductor modules and the power semiconductor circuit, respectively, no longer have to be accommodated or encapsulated in housings since the design enables an arrangement with passivated elements.

In addition, according to an embodiment the individual components of the power semiconductor circuit are enabled to be placed and mounted in a fully automated manner. In one embodiment, the components are supplied on belts and the electrical connections to one another are produced by bonding and/or laser welding. In another embodiment, the base plate comprises a metal, for example aluminum.

In one embodiment the substrate is a ceramic substrate and the ceramic bottom side of the substrate is adhesively bonded to the base plate. For this purpose, the substrate and/or the placement region of the substrate provided on the base plate can be printed with an adhesive in advance. Compared to conventional mounting technology, the substrate does not have to be pretreated (for example metallization as a pretreatment) on the bottom side.

The base plate can be formed as an air heat sink or a liquid-cooled cooling setup. This ensures not only homogenized heat distribution but effective heat dissipation through the base plate.

Another embodiment lies in the deposition of a metallization for conducting high currents on the top side of the substrate. The thickness of this metallization layer is selected depending upon the application (demand on current conduction) and can be, for example, in the range of 50 μm to 4 mm, if copper or aluminum layers are used.

With regard to the management of heat loss and in the case of a multiplicity of heat generating devices, an embodiment is the arrangement of a plurality of power semiconductor modules having power semiconductors, of which each generates heat loss, in a distributed manner on the top side of the base plate.

A method of manufacturing a power semiconductor circuit, may comprise the steps of arranging at least one electronic power device having a contact area on the top side on a substrate, laminating a film having a pad on for contacting the contact area, fitting a thermally conductive base plate with the substrate by directly connecting the bottom side of the substrate to the base plate by using a thermally conductive adhesive bond, and adhesively bonding other circuits having a flat design and/or devices with bondable contacts to the base plate and are contacted to pads formed on the film.

An aspect of the method is the ability to carry out all steps of the method fully automated. For this purpose, the at least one power semiconductor module has, for example, bondable pads which can be used to connect the power semiconductor modules to one another and to other flat assemblies, such as a control circuit. In an embodiment, the control circuit is arranged on a ceramic, for example in form of a thick-film-hybrid, and is likewise adhesively bonded to the base plate. In addition, for example in the case of a converter circuit, discrete components, for example storage capacitors, can be provided with bondable pads and can be arranged on the base plate. These and other components, for example contact terminals or contact plugs for external electrical contacts, are in another embodiment automatically supplied to the mounting process in trays, on belts or on rails and in total connected to the base plate by means of adhesive bonds. Complicated connecting techniques, for example screw connections, can therefore be abandoned. However, adhesive bonding, crimping, latching using latching hooks, screwing using threaded elements etc. are as well suitable, in addition to adhesive bonds, for indirectly or directly fastening printed circuit boards and/or assemblies and/or contact elements and/or passive devices and/or elements for contacting etc. at a distance from the base plate or without a distance from the base plate.

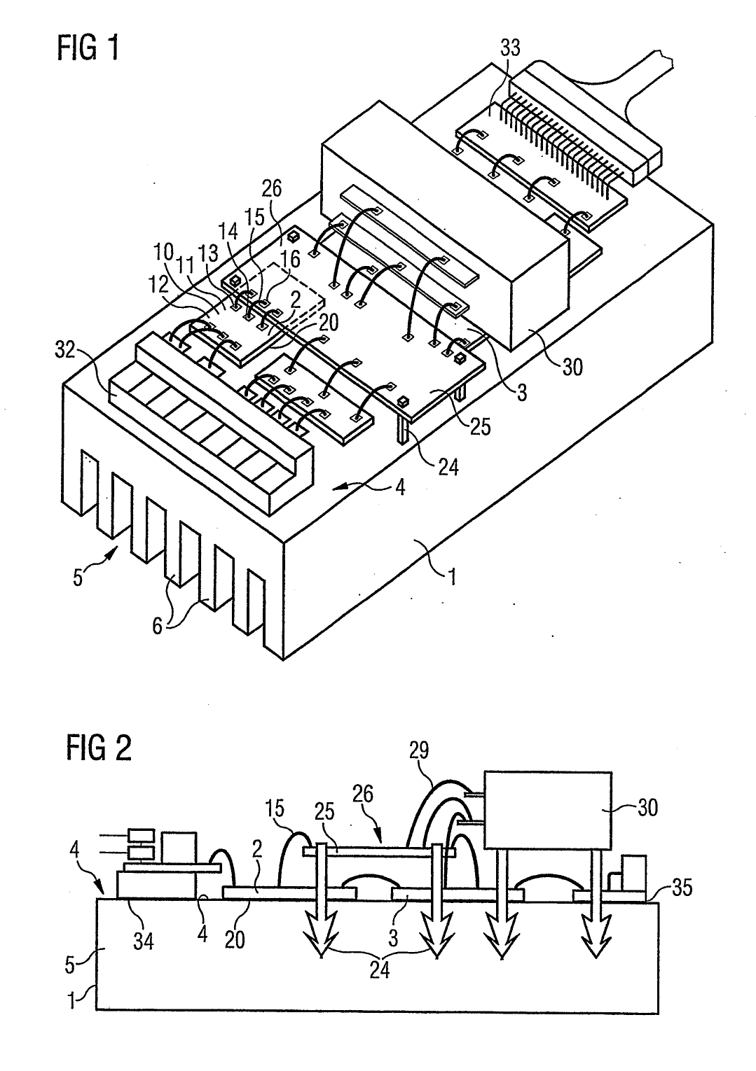

FIGS. 1 and 2 show a power semiconductor circuit which is arranged on an aluminum base plate 1. A plurality of power semiconductor modules, for example 2, 3, is arranged on the flat top side 4 of the base plate. The base plate has the form of a cooling device 5 which has cooling ribs 6 as an air cooler. The base plate thus has a dual function: it carries the power semiconductor circuit and simultaneously ensures that the heat loss produced during operation is very effectively dissipated.

By way of example, the module 2 is used to describe the basic design of module 2: an electronic power device, for example an IGBT, is soldered to the top side 10 of a substrate 11 which comprises a ceramic. For that purpose, a patterned metallization conducting high currents is deposited on the substrate.

A film 12 of the kind initially described which has conductor paths and pads establishing electrical contacts is laminated onto the device. These connections may also comprise an electrical contact between a contact area (pad) on the top side of the device and a corresponding pad on the film, as initially explained in detail and described in the German patent application having the official file reference 103 14 172.3. The film 12 has pads 13, 14 on the top side, and the pads are electrically connected to corresponding pads (for example 16) via bonding wires (for example 15). This module is characterized by a very flat and compact design.

The substrate 11 itself is directly adhesively bonded to the top side 4 of the base plate using highly thermally conductive adhesive 20 (for example silicone). In particular, a metallization on the bottom side of the substrate is not provided, resulting in the adhesive or the adhesive bond 20 connecting the material pairing ceramic/aluminum.

To achieve a uniform heat distribution, the power semiconductor modules 2, 3 are arranged in a distributed manner on the top side 4.

A printed circuit board 25 which is fitted with a control circuit 26 and which is connected to the module 2 and to other components via bonding wires (for example 15, 29) is arranged on posts 24 above the module 2. Another component illustrated as an example is an intermediate storage capacitor 30.

In order to connect the power semiconductor circuit to external components and/or control circuits and/or elements to be switched, terminal blocks 32, 33 having, for example, screw or plug connections on the outside for external connections are provided at both ends of the base plate. These terminal blocks can be mounted using surface mounting technology as well having bondable pads and are connected to the base plate by adhesive bonds 34, 35 (FIG. 2).

For manufacturing the power semiconductor circuit, at least one electronic power device with a contact area on the top side is at first mounted on the substrate 11 and the film 12 having a pad is laminated on for contacting the contact area as described above. This unit is afterwards connected to the top side 4 of the base plate 1 by directly adhesively bonding the bottom side of the substrate to the base plate using thermally conductive adhesive. Furthermore, other components and/or circuits having a flat design and bondable contacts are adhesively bonded to the base plate. Pads formed on the module are subsequently connected to the other components, for example by copper wire bonding, according to the circuit to be implemented.

A very compact power semiconductor circuit, for example a converter circuit, which can be inserted into a relatively small housing (not illustrated) is thus realized. An encapsulating compound can be introduced in the housing if necessary. In terms of electrical aspects, however, caused by the fact that the modules can be passivated in a relatively simple fashion, it is possible to abandon an encapsulation.

The power semiconductor circuit may enable optimum use of the space-saving possibilities which result from the flat design of a power semiconductor module arranged in the form of layers. Finally, another advantage is that for internal connection and mounting this power semiconductor circuit does not require internal screw connections and thermolubes.

### LIST OF REFERENCE SYMBOLS

1 Base plate
2 Power semiconductor module
3 Power semiconductor module
4 Top side
5 Cooling equipment
6 Cooling ribs
10 Top side
11 Substrate
12 Film
13 Pad
14 Pad
15 Bonding wire
16 Pad
20 Adhesive bond
24 Posts
25 Printed circuit board
26 Control circuit
29 Bonding wire
30 Intermediate storage capacitor
32 Terminal block
33 Terminal block
34 Adhesive bond
35 Adhesive bond

What is claimed is:

1. A power semiconductor circuit, comprising
a power semiconductor module in the form of a flat assembly in which at least one electronic power device is arranged on a substrate and in which the at least one electronic power device has a contact area on the top side which is in contact with a pad of a laminated film,
the substrate being directly fastened to a thermally conductive base plate which acts as a cooling element.

2. The power semiconductor circuit as claimed in claim 1, wherein the substrate is a ceramic substrate and adhesively bonded with its ceramic bottom side to the base plate.

3. The power semiconductor circuit as claimed in claim 1, wherein the base plate is an air heat sink.

4. The power semiconductor circuit as claimed in claim 1, wherein the base plate is liquid-cooled.

5. The power semiconductor circuit as claimed in claim 1, wherein a metalization conducting high currents is deposited on the top side of the substrate.

6. The power semiconductor circuit as claimed in claim 1, wherein a plurality of power semiconductor modules comprise power semiconductors individually generating heat loss, and are arranged in a distributed manner on the top side of the base plate.

7. The power semiconductor circuit as claimed in claim 1, wherein the substrate is directly adhesively bonded to the thermally conductive base plate with a thermally conductive adhesive.

8. The power semiconductor circuit as claimed in claim 1, wherein printed circuit boards and/or assemblies and/or contact elements and/or passive devices and/or elements for contacting are arranged in a distributed manner on the top side of the base plate.

9. The power semiconductor circuit as claimed in claim 8, wherein the printed circuit boards and/or assemblies and/or contact elements and/or passive devices and/or elements for contacting are directly or indirectly fastened to the base plate.

10. A method for producing a power semiconductor circuit, comprising the steps of:
arranging at least one electronic power device having a contact area on the top side on a substrate,
laminating a film having a pad for contacting the contact area on the at least one electronic power device,
fitting a thermally conductive base plate with the substrate by directly connecting the bottom side of the substrate to the base plate by using a thermally conductive adhesive bond,
other circuits having a flat design and/or devices having bondable contacts are adhesively bonded to the base plate, and connecting the circuits and/or devices to pads formed on the film.

11. A power semiconductor circuit, comprising
a power semiconductor module in the form of a flat assembly in which at least one electronic power device is arranged on a substrate and in which the at least one electronic power device has a contact area on the top side which is in contact with a pad of a laminated film,
the substrate being directly fastened to a thermally conductive base plate which acts as a cooling element,
wherein a plurality of power semiconductor modules comprise power semiconductors individually generating heat loss, and are arranged in a distributed manner on the top side of the base plate.

12. The power semiconductor circuit as claimed in claim 11, wherein the substrate is a ceramic substrate and adhesively bonded with its ceramic bottom side to the base plate.

13. The power semiconductor circuit as claimed in claim 11, wherein the base plate is an air heat sink.

14. The power semiconductor circuit as claimed in claim 11, wherein the base plate is liquid-cooled.

15. The power semiconductor circuit as claimed in claim 11, wherein a metalization conducting high currents is deposited on the top side of the substrate.

16. The power semiconductor circuit as claimed in claim 11, wherein the substrate is directly adhesively bonded to the thermally conductive base plate with a thermally conductive adhesive.

17. The power semiconductor circuit as claimed in claim 11, wherein printed circuit boards and/or assemblies and/or contact elements and/or passive devices and/or elements for contacting are arranged in a distributed manner on the top side of the base plate.

18. The power semiconductor circuit as claimed in claim 17, wherein the printed circuit boards and/or assemblies and/or contact elements and/or passive devices and/or elements for contacting are directly or indirectly fastened to the base plate.
